(19) United States
(12) Patent Application Publication
(10) Pub. No.: US 2025/0226276 A1
(43) Pub. Date: Jul. 10, 2025

(54) SEMICONDUCTOR DEVICE

(71) Applicant: FUJI ELECTRIC CO., LTD., Kawasaki-shi (JP)

(72) Inventor: Takashi SAITO, Matsumoto-city (JP)

(73) Assignee: FUJI ELECTRIC CO., LTD., Kawasaki-shi (JP)

(21) Appl. No.: 19/093,969

(22) Filed: Mar. 28, 2025

Related U.S. Application Data
(63) Continuation of application No. PCT/JP2024/008106, filed on Mar. 4, 2024.

(30) Foreign Application Priority Data
Apr. 13, 2023 (JP) 2023-065562

(51) Int. Cl. H01L 23/31; H01L 23/00; H01L 23/29; H01L 23/373; H01L 23/495

(52) U.S. Cl. CPC H01L 23/3135; H01L 23/295; H01L 23/49517; H01L 24/26; H01L 24/32; H01L 23/3735; H01L 24/29; H01L 24/48; H01L 24/73; H01L 24/83; H01L 2224/26125; H01L 2224/26155; H01L 2224/29139; H01L 2224/32059; H01L 2224/32227; H01L 2224/32245; H01L 2224/48227; H01L 2224/73265; H01L 2224/8384; H01L 2924/35121

(57) ABSTRACT

A semiconductor device includes a conductive plate having a main surface, a semiconductor chip arranged to be opposed to the main surface of the conductive plate, a sintered bonding layer arranged between the conductive plate and the semiconductor chip, a sealing resin provided to seal the semiconductor chip and the sintered bonding layer, and a primer layer arranged between the sintered bonding layer and the sealing resin, wherein a first outer edge of a bonding interface between the sintered bonding layer and the conductive plate is located on the inside of an outer circumference of the semiconductor chip and is located on the inside of a second outer edge of a bonding interface between the sintered bonding layer and the semiconductor chip.

### CROSS-REFERENCE TO RELATED APPLICATION

This application is a Continuation of PCT Application No. PCT/JP2024/008106, filed on Mar. 4, 2024, and claims the priority of Japanese Patent Application No. 2023-065562, filed on Apr. 13, 2023, the content of which are incorporated herein by reference.

### TECHNICAL FIELD

The present invention relates to semiconductor devices (semiconductor modules) equipped with power semiconductor chips.

### BACKGROUND ART

WO2023/286432A1 discloses a semiconductor device, which includes a conductive plate having a main surface, a semiconductor chip arranged to be opposed to the main surface of the conductive plate, and a bonding layer (a sintered bonding layer) including porous sintered material and arranged between the conductive plate and the semiconductor chip, wherein a first outer edge of a bonding interface between the sintered bonding layer and the conductive plate is located on an inside of an outer circumference of the semiconductor chip and is located on an inside of a second outer edge of a bonding interface between the sintered bonding layer and the semiconductor chip, so as to avoid variation in life span.

U.S. Ser. No. 10/535,628B2 discloses a method of printing sintering paste either on a substrate or a bottom surface of a die.

JP6399906B2 discloses that a bonding layer includes a first bonding layer provided at a position on the inside of an end part of a semiconductor element, and a second bonding layer provided on the inside of the end part of the semiconductor element and further on the outside of the first bonding layer, in which the second bonding layer includes metallic sintering bonding material having a smaller grain diameter than the material included in the first bonding layer.

### SUMMARY OF THE INVENTION

### Technical Problem

Such a conventional semiconductor device in which the semiconductor chip and the conductive plate are bonded together with the sintered bonding layer interposed, as disclosed in WO2023/286432A1, may cause a separation at the interface between the sealing resin and the sintered bonding layer if sealed with sealing resin such as epoxy resin for high heat resistance, and thus may lead to variation in life span.

In view of the foregoing problems, the present invention provides a semiconductor device having a configuration capable of avoiding a separation at an interface between a sintered bonding layer and a sealing resin and also reducing variation in life span.

### Solution to Problem

An aspect of the present invention inheres in a semiconductor device including: a conductive plate having a main surface; a semiconductor chip arranged to be opposed to the main surface of the conductive plate; a sintered bonding layer arranged between the conductive plate and the semiconductor chip; a sealing resin provided to seal the semiconductor chip and the sintered bonding layer; and a primer layer arranged between the sintered bonding layer and the sealing resin, wherein a first outer edge of a bonding interface between the sintered bonding layer and the conductive plate is located on an inside of an outer circumference of the semiconductor chip and is located on an inside of a second outer edge of a bonding interface between the sintered bonding layer and the semiconductor chip.

### BRIEF DESCRIPTION OF THE DRAWINGS

FIG. 1 is a cross-sectional view illustrating a semiconductor device according to a first embodiment;

FIG. 2 is a plan view illustrating the semiconductor device according to the first embodiment;

FIG. 3 is a cross-sectional view as viewed from direction A-A in FIG. 2;

FIG. 4 is a cross-sectional image of the semiconductor device according to the first embodiment;

FIG. 5 is a cross-sectional view illustrating a semiconductor device of a first comparative example;

FIG. 6 is a cross-sectional view illustrating a semiconductor device of a second comparative example;

FIG. 7 is a cross-sectional view illustrating a semiconductor device of a third comparative example;

FIG. 8 is a cross-sectional view illustrating a semiconductor device of a fourth comparative example;

FIG. 9 is a cross-sectional view illustrating a semiconductor device of a fifth comparative example;

FIG. 10 is another cross-sectional view as viewed from direction A-A in FIG. 2;

FIG. 11 is a table showing results of a reliability test executed for the example and the first to fifth comparative examples;

FIG. 12 is a schematic view illustrating a method of manufacturing the semiconductor device according to the first embodiment;

FIG. 13 is a schematic view continued from FIG. 12, illustrating the method of manufacturing the semiconductor device according to the first embodiment;

FIG. 14 is a schematic view continued from FIG. 13, illustrating the method of manufacturing the semiconductor device according to the first embodiment;

FIG. 15 is a schematic view continued from FIG. 14, illustrating the method of manufacturing the semiconductor device according to the first embodiment;

FIG. 16 is a schematic view continued from FIG. 15, illustrating the method of manufacturing the semiconductor device according to the first embodiment;

FIG. 17 is a cross-sectional view illustrating a semiconductor device according to a second embodiment;

FIG. 18 is a cross-sectional view illustrating a semiconductor device according to a third embodiment;

FIG. 19 is a cross-sectional view illustrating a semiconductor device according to a fourth embodiment;

FIG. 20 is a cross-sectional view illustrating a semiconductor device according to a fifth embodiment;

FIG. 21 is a cross-sectional view illustrating a semiconductor device according to a sixth embodiment;

FIG. 22 is a cross-sectional view illustrating a semiconductor device according to a seventh embodiment;

FIG. 23 is a schematic view illustrating a method of manufacturing the semiconductor device according to the seventh embodiment;

FIG. 24 is a schematic view continued from FIG. 23, illustrating the method of manufacturing the semiconductor device according to the seventh embodiment;

FIG. 25 is a schematic view continued from FIG. 24, illustrating the method of manufacturing the semiconductor device according to the seventh embodiment; and

FIG. 26 is a cross-sectional view illustrating a semiconductor device according to an eighth embodiment.

### DETAILED DESCRIPTION

With reference to the drawings, first to eighth embodiments will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to eighth embodiments described below merely illustrate schematically devices and methods for specifying and giving shapes to the technical idea of the present invention, and the span of the technical idea is not limited to materials, shapes, structures, and relative positions of elements described herein.

In the specification, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

### First Embodiment

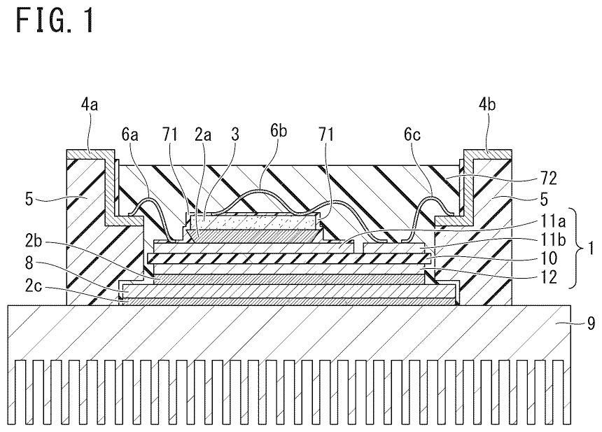

As illustrated in FIG. 1, a semiconductor device (a semiconductor module) according to a first embodiment includes an insulated circuit substrate 1, a semiconductor chip 3 arranged to be opposed to a main surface (the top surface) of the insulated circuit substrate 1, and a sintered bonding layer 2a arranged between the insulated circuit substrate 1 and the semiconductor chip 3. The semiconductor device according to the first embodiment further includes a sealing resin 72 provided to seal the semiconductor chip 3 and the sintered bonding layer 2a, and a primer layer 71 arranged between the sintered bonding layer 2a and the sealing resin 72.

The insulated circuit substrate 1 may be a direct copper bonded (DCB) substrate or an active metal brazed (AMB) substrate, for example. The insulated circuit substrate 1 includes an insulating plate 10, conductive plates (circuit plates) 11a and 11b arranged on the top surface of the insulating plate 10, and a conductive plate (a metal plate) 12 arranged on the bottom surface of the insulating plate 10. The insulating plate 10 is a ceramic substrate including aluminum oxide (Al₂O₃), aluminum nitride (AlN), or silicon nitride (Si₃N₄), or a resin-insulating substrate including polymer material, for example. The conductive plates 11a and 11b and the conductive plate 12 are each a conductor foil of metal such as copper (Cu) and aluminum (Al), for example.

The sintered bonding layer 2a includes porous sintering material. The sintered bonding layer 2a can be formed by sintering of metallic grain paste (conductive paste) in which grains of metal such as gold (Au), silver (Ag), or copper (Cu) are dispersed in an organic component and led to be in a paste state, or by sintering of bonding material in a sheet state containing metallic grains, for example. The metallic grains have a fine grain diameter in a range of about several nanometers or greater and several micrometers or smaller. The use of the silver (Ag)-based sintering material, which can be bonded at a low temperature and led to have the same fusing point as Ag after the bonding, can provide a bonding layer having high heat resistance and high reliability with no necessity of increasing the bonding temperature.

The semiconductor chip 3 is arranged to be opposed to the main surface (the top surface) of the conductive plate 11a. The semiconductor chip 3 as used herein can be an insulated gate bipolar transistor (IGBT), a field-effect transistor (FET), a static induction (SI) thyristor, a gate turn-off (GTO) thyristor, or a freewheeling diode (FWD), for example. The semiconductor chip 3 may be implemented by a silicon (Si) substrate, or a compound semiconductor substrate of a wide-bandgap semiconductor including silicon carbide (SiC), gallium nitride (GaN), or gallium oxide (Ga₂O₃), for example. A bottom-surface electrode of the semiconductor chip 3 including gold (Au) or the like is bonded to the conductive plate 11a with the sintered bonding layer 2a interposed.

While FIG. 1 illustrates the case of including the single semiconductor chip 3, the number of the semiconductor chips provided can be determined as appropriate depending on a current capacity of the semiconductor module, for example, and the semiconductor module may include two or more semiconductor chips.

A case 5 is provided to surround the outer circumference of the insulated circuit substrate 1 and the semiconductor chip 3. The case 5 is formed of thermoplastic resin such as polyphenylene sulfide (PPS) and polybutylene terephthalate (PBT), for example. External terminals 4a and 4b are fixed to the case 5. The semiconductor chip 3, the conductive plates 11a and 11b, and the external terminals 4a and 4b are electrically connected to each other via bonding wires 6a, 6b, and 6c.

The case 5 is filled with sealing resin 72 so as to seal the sintered bonding layer 2a and the semiconductor chip 3. The sealing resin 72 includes thermosetting resin such as epoxy resin, phenol resin, and maleimide resin, for example. The sealing resin 72 can further include inorganic filler other than the resin main agent such as epoxy resin, phenol resin, and maleimide resin. The inorganic filler may be a metal oxide or a metal nitride including any of fused silica, silica (silicon oxide), alumina, aluminum hydroxide, titania, zirconia, aluminum nitride, talc, clay, mica, or glass fiber, or two or more of these materials mixed together.

The amount of the inorganic filler included is in a range of about 10% by mass or greater and 90% by mass or smaller with respect to the entire mass of the sealing resin 72, but is not limited to this range. An average grain diameter of the inorganic filler is in a range of about 0.2 micrometers or greater and 20 micrometers or smaller, but is not limited to this range. The average grain diameter as used herein refers to a grain diameter in a grain distribution corresponding to an accumulated value of 50% obtained by a laser diffraction scattering method.

A coefficient of linear thermal expansion of the sealing resin 72 is in a range of about 2×10⁻⁶/° C. or greater and 24×10⁻⁶/° C. or smaller, for example, but is not limited to this range. Setting the coefficient of linear thermal expansion of the sealing resin 72 within a range of the coefficient of linear thermal expansion of each of the wiring members such as the bonding wires 6a, 6b, and 6c, the semiconductor chip 3, the sintered bonding layer 2a, and the insulated circuit substrate 1, can obtain a stress reduction effect.

The primer layer 71 is provided between the sintered bonding layer 2a and the sealing resin 72. FIG. 1 illustrates the case in which the primer layer 71 is provided between the sealing resin 72 and each of the conductive plate 11a, the sintered bonding layer 2a, and the semiconductor chip 3. The primer layer 71 is only required to be provided at least between the sintered bonding layer 2a and the sealing resin 72. For example, the primer layer 71 may be selectively provided only between the sintered bonding layer 2a and the sealing resin 72. The primer layer 71 may be provided not only between the sealing resin 72 and each of the conductive plate 11a, the sintered bonding layer 2a, and the semiconductor chip 3 but also between the sealing resin 72 and each of the conductive plate 11b and the insulating plate 10.

The primer layer 71 has the properties that can ensure adhesion between the sintered bonding layer 2a and the sealing resin 72. The primer layer 71 can be obtained by spray application, immersion, and application with a dispenser, for example. A thickness of the primer layer 71 is in a range of about 1 micrometer or greater and 15 micrometers or smaller, for example, but is not limited to this range. The thickness of the primer layer 71 can be determined as appropriate depending on the viscosity of the primer layer 71, the immersed number by the immersion, the applied amount by the spray application or the application with a dispenser, and the like.

The primer layer 71 includes resin different from that included in the sealing resin 72. The primer layer 71 mainly includes polyamide, polyimide, or polyamide imide, for example. The primer layer 71 has a greater coefficient of linear thermal expansion than the sealing resin 72. The coefficient of linear thermal expansion of the primer layer 71 is in a range of about 40×10⁻⁶/° C. or greater and 100×10⁻⁶/° C. or smaller, for example, but is not limited to this range.

To reduce a stress caused at the interface between the primer layer 71 and the sealing resin 72 more reliably, the coefficient of linear thermal expansion al of the primer layer 71 and the coefficient of linear thermal expansion α2 of the sealing resin 72 preferably meet the following expression (1):

$$100 \times {10}^{- 6} / ° C . \geq α1 > α2 \geq 10 \times {10}^{- 6} / ° C . \qquad ( 1 )$$

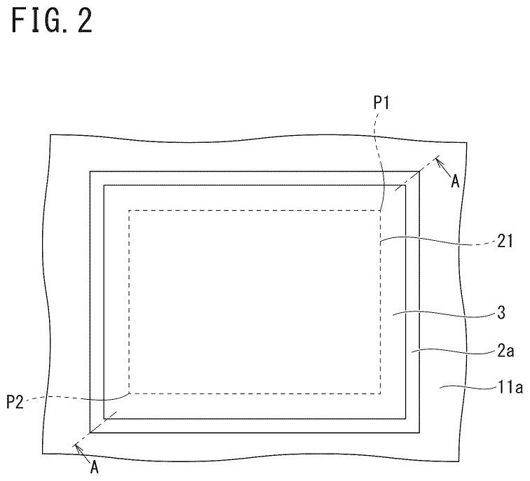

FIG. 2 is a plan view illustrating the conductive plate 11a of the insulated circuit substrate 1 and the semiconductor chip 3 illustrated in FIG. 1. As illustrated in FIG. 2, the semiconductor chip 3 has a rectangular planar pattern. The semiconductor chip 3 has a size of about 5 millimeters×5 millimeters, for example, but is not limited to this size. The sintered bonding layer 2a has a rectangular planar pattern. The outer edge of the sintered bonding layer 2a on the top surface side (toward the semiconductor chip 3) is located on the outside of the outer circumference of the semiconductor chip 3. The outer edge of the sintered bonding layer 2a on the top surface side (toward the semiconductor chip 3) may conform to the outer circumference of the semiconductor chip 3, or may be located on the inside of the outer circumference of the semiconductor chip 3.

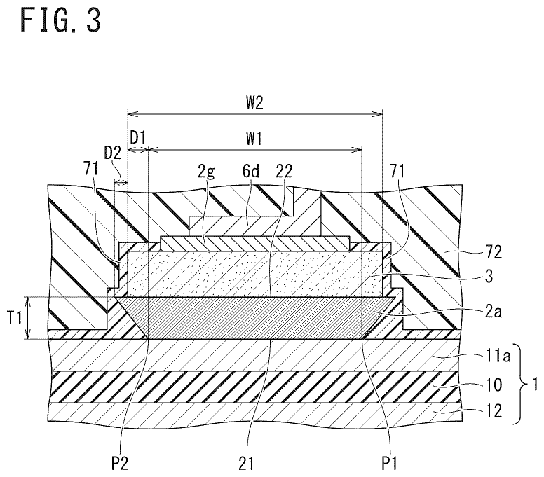

FIG. 3 is a cross-sectional view taken along the diagonal line of the semiconductor chip 3 as viewed from direction A-A in FIG. 2. As illustrated in FIG. 3, the sintered bonding layer 2a has a substantially trapezoidal shape (a tapered shape or an inverted fillet shape) in cross section having a longer length at the upper base on the top surface side (toward the semiconductor chip 3) than at the lower base on the bottom surface side (toward the conductive plate 11a). While FIG. 3 illustrates the case in which the side surfaces of the sintered bonding layer 2a are each a straight surface, the side surfaces of the sintered bonding layer 2a may each be a curved surface convex either to the outside or to the inside. For example, the respective surfaces of the sintered bonding layer 2a toward the conductive plate 11a may be convex toward the conductive plate 11a on the outside of the outer edge of a bonding interface 21 between the sintered bonding layer 2a and the conductive plate 11a.

The outer edge of the bonding interface 21 between the sintered bonding layer 2a and the conductive plate 11a has a triple-junction point at which the sintered bonding layer 2a, the conductive plate 11a, and the primer layer 71 are in contact with each other. A width W1 of the bonding interface 21 between the sintered bonding layer 2a and the conductive plate 11a is narrower than a width W2 of a bonding interface 22 between the sintered bonding layer 2a and the semiconductor chip 3. The outer edge of the bonding interface 22 between the sintered bonding layer 2a and the semiconductor chip 3 conforms to the outer circumference of the semiconductor chip 3. FIG. 2 schematically indicates the bonding interface 21 between the sintered bonding layer 2a and the conductive plate 11 by the broken line.

As illustrated in FIG. 1 to FIG. 3, the outer edge of the bonding interface 21 between the sintered bonding layer 2a and the conductive plate 11a is located on the inside of the outer circumference of the semiconductor chip 3 and is located on the inside of the outer edge of the bonding interface 22 between the sintered bonding layer 2a and the semiconductor chip 3. This configuration provides stress-concentrated parts P1 and P2 at the outer edge of the bonding interface 21 between the sintered bonding layer 2a and the conductive plate 11a. The stress-concentrated parts P1 and P2 tend to cause cracks that gradually proceed toward the middle of the sintered bonding layer 2a to increase thermal resistance, leading to a break in the semiconductor device. FIG. 2 illustrates the planar pattern with the case in which the stress-concentrated parts P1 and P2 are located at the outer edge of the bonding interface 21 between the sintered bonding layer 2a and the conductive plate 11a (indicated by the broken line), and cracks tend to be caused particularly from any of the four corners of the rectangular pattern defined by the bonding interface 21.

Namely, the configuration of the semiconductor device according to the first embodiment, in which the outer edge of the bonding interface 21 between the sintered bonding layer 2a and the conductive plate 11a is located on the inside of the outer circumference of the semiconductor chip 3 and is located on the inside of the outer edge of the bonding interface 22 between the sintered bonding layer 2a and the semiconductor chip 3, provides the stress-concentrated parts P1 and P2 at the outer edge of the bonding interface 21 so as to positively cause cracks starting from the stress-concentrated parts P1 and P2. This configuration enables rate limiting of a life span through the sintered bonding layer 2a to intentionally lead to a break in the semiconductor device, so as to reduce variation in the life span of semiconductor devices.

A distance D1 between the outer edge of the bonding interface 21 between the sintered bonding layer 2a and the conductive plate 11a and the outer edge of the bonding interface 22 between the sintered bonding layer 2a and the semiconductor chip 3 is in a range of about 5 micrometers or greater and 50 micrometers or smaller, for example, but is not limited to this range. A thickness T1 of the sintered bonding layer 2a is in a range of about 10 micrometers or greater and 50 micrometers or less for example, but is not limited to this range. The distance D1 is about 1/2500 or greater and 1/50 or less of the length of the diagonal line of the semiconductor chip 3 in the planar pattern, and is about 1/1250 or greater and 1/50 or less of the thickness T1 of the sintered bonding layer 2a, but is not limited to this case, and can be changed as appropriate depending on the type of the sintered bonding layer 2a, the thickness T1 of the sintered bonding layer 2a, and the size of the semiconductor chip 3, for example.

The stress concentrated on the stress-concentrated parts P1 and P2 increases as the outer edge of the bonding interface 21 between the sintered bonding layer 2a and the conductive plate 11a is located on the inner side of the semiconductor chip 3 so as to increase the distance D1, and cracks starting from the stress-concentrated parts P1 and P2 thus tend to be caused more easily. The adjustment of the distance D1 therefore can regulate the cause of cracks starting from the stress-concentrated parts P1 and P2, and can control the life span of the semiconductor device accordingly.

The outer edge of the sintered bonding layer 2a on the top surface side (toward the semiconductor chip 3) projects to the outside by a distance D2 from the outer circumference of the semiconductor chip 3. The distance D2 is in a range of about 1 micrometer or greater and 30 micrometers or smaller, but is not limited to this range. The part of the sintered bonding layer 2a projecting to the outside from the outer circumference of the semiconductor chip 3 is not necessarily provided. For example, the part of the sintered bonding layer 2a projecting to the outside from the outer circumference of the semiconductor chip 3 may be removed by air blowing or washing, for example, before the execution of sintering of the sintered bonding layer 2a. In such a case, the outer edge of the sintered bonding layer 2a on the top surface side (toward the semiconductor chip 3) may conform to the outer circumference of the semiconductor chip 3, or may be located on the inside of the outer circumference of the semiconductor chip 3.

The sintering material included in the sintered bonding layer 2a is porous so as to have pores (holes) between metal grains. A porosity between metal grains in the sintered bonding layer 2a is higher in a region located on the inside of the outer edge of the bonding interface 21 between the sintered bonding layer 2a and the conductive plate 11a than in a region located on the inside of the outer edge of the bonding interface 22 between the sintered bonding layer 2a and the semiconductor chip 3 and on the outside of the outer edge of the bonding interface 21 between the sintered bonding layer 2a and the conductive plate 11a. The part of the sintered bonding layer 2a located on the inside of the outer edge of the bonding interface 21 between the sintered bonding layer 2a and the conductive plate 11a thus tends to cause cracks more easily than the part of the sintered bonding layer 2a located on the inside of the outer edge of the bonding interface 22 between the sintered bonding layer 2a and the semiconductor chip 3 and on the outside of the outer edge of the bonding interface 21 between the sintered bonding layer 2a and the conductive plate 11a, and the cracks caused tend to further advance, so as to promote a break in the semiconductor device accordingly.

The primer layer 71 penetrates into a region between the sintered bonding layer 2a and the conductive plate 11a corresponding to a part having a distance (D1+D2) from the outer edge of the sintered bonding layer 2a on the top surface side (toward the semiconductor chip 3) to the outer edge of the bonding interface 21. In the semiconductor device according to the first embodiment, only the primer layer 71 penetrates into the region between the sintered bonding layer 2a and the conductive plate 11a. The outer circumferential surface of the primer layer 71 in the position corresponding to the side surface of the sintered bonding layer 2a is a flat surface parallel to the vertical direction. The thickness of the primer layer 71 in the position corresponding to the side surface of the sintered bonding layer 2a gradually increases toward the conductive plate 11a.

The outer circumferential surface of the primer layer 71 in the position corresponding to the side surface of the sintered bonding layer 2a may either incline with respect to the vertical direction or have a curved surface. The thickness of the primer layer 71 in the position corresponding to the side surface of the sintered bonding layer 2a may be either substantially constant or gradually decreased toward the conductive plate 11a.

While FIG. 1 illustrates the case in which the bonding wire 6b is connected as a wiring member to the semiconductor chip 3, FIG. 3 illustrates the case in which the lead frame 6d is connected as a wiring member to the semiconductor chip 3. The lead frame 6d is connected to the semiconductor chip 3 with a bonding layer 2g interposed. The bonding layer 2g includes sintering material or solder. The bonding layer 2g may include the material that is either the same as or different from the material included in the sintered bonding layer 2a.

As illustrated in FIG. 1, a heat-releasing base 8 including metal such as copper (Cu) is provided on the bottom surface side of the insulated circuit substrate 1 with a bonding layer 2b interposed. A heat-releasing fin 9 including metal such as copper (Cu) is provided on the bottom surface side of the heat-releasing base 8 with a bonding layer 2c interposed.

The bonding layers 2b and 2c each include sintering material, solder, or thermal interface material (TIM), for example. TIM as used herein can be thermal-conductive material (a thermal compound), such as thermal-conductive grease, an elastomer sheet, room temperature vulcanization (RTV) rubber, gel, phase-change material, and silver wax. The respective bonding layers 2b and 2c may include the material that is either the same as or different from the material included in the sintered bonding layer 2a.

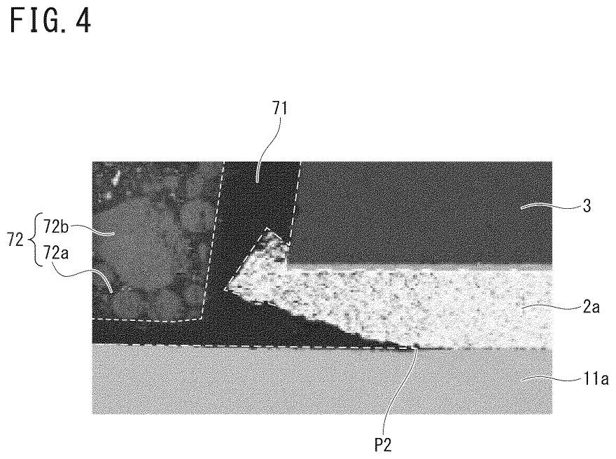

FIG. 4 is a cross-sectional image showing a part of the semiconductor device according to the first embodiment. The primer layer 71 is provided between the sintered bonding layer 2a and the sealing resin 72. The sealing resin 72 includes resin main agent 72a and inorganic filler 72b. The primer layer 71 penetrates into a region between the sintered bonding layer 2a and the conductive plate 11a.

### Comparative Examples

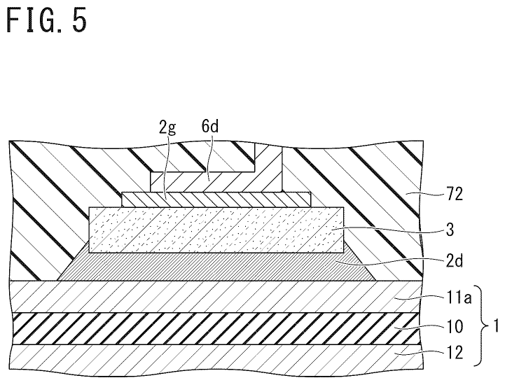

A semiconductor device of a first comparative example is described below. As illustrated in FIG. 5, the semiconductor device of the first comparative example differs from the semiconductor device according to the first embodiment illustrated in FIG. 3 in that a sintered bonding layer 2d has a fillet shape in contact with the side surfaces at a lower part of the semiconductor chip 3 in which the outer circumference of the sintered bonding layer 2d on the bottom surface side is located on the outside of the outer circumference of the semiconductor chip 3, and the side surfaces of the sintered bonding layer 2d are inclined to be widened toward the bottom side, in that the primer layer 71 is not provided between the sintered bonding layer 2d and the sealing resin 72, and in that the sealing resin 72 includes gel.

The semiconductor device of the first comparative example including the sintered bonding layer 2d has a longer life span than the case of including a bonding layer made from solder. However, the sintered bonding layer 2d, which has high heat resistance and high reliability, does not serve as a part that can control the rate limiting of the life span, and the semiconductor device thus may be suddenly damaged because of cracks caused in the semiconductor chip 3 or the insulated circuit substrate 1, for example, other than the sintered bonding layer 2d. This leads the semiconductor device of the first comparative example to cause variation in the life span, which could further lead to serious malfunction. In view of this, a malfunction mode preferably functions such that deterioration (cracks) in the bonding layer is gradually promoted and the semiconductor device causes a break in association with an increase in thermal resistance, for example, as in the case of the conventional case of being made from solder. Further, the configuration of the semiconductor device of the first comparative example in which the sealing resin 72 includes gel impedes an increase in high-heat resistance.

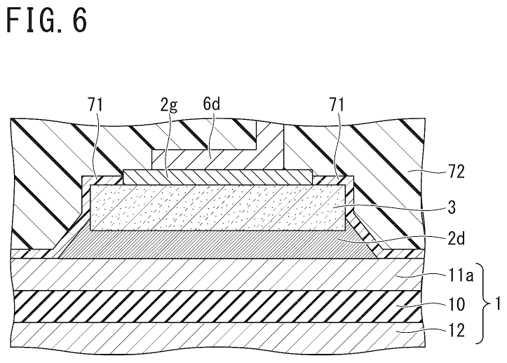

Next, a semiconductor device of a second comparative example is described below. As illustrated in FIG. 6, the semiconductor device of the second comparative example differs from the semiconductor device according to the first embodiment illustrated in FIG. 3 in that the sintered bonding layer 2d has a fillet shape in contact with the side surfaces at a lower part of the semiconductor chip 3 in which the outer circumference of the sintered bonding layer 2d on the bottom surface side is located on the outside of the outer circumference of the semiconductor chip 3, and the side surfaces of the sintered bonding layer 2d are inclined to be widened toward the bottom side. The semiconductor device of the second comparative example also does not cause a break in the sintered bonding layer 2d, leading to variation in the life span accordingly.

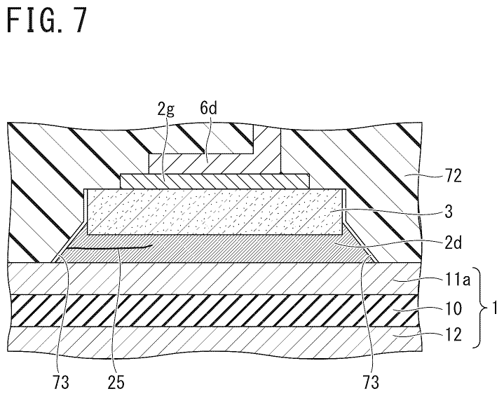

Next, a semiconductor device of a third comparative example is described below. As illustrated in FIG. 7, the semiconductor device of the third comparative example differs from the semiconductor device according to the first embodiment illustrated in FIG. 3 in that the sintered bonding layer 2d has a fillet shape in contact with the side surfaces at the lower part of the semiconductor chip 3 in which the outer circumference of the sintered bonding layer 2d on the bottom surface side is located on the outside of the outer circumference of the semiconductor chip 3, and the side surfaces of the sintered bonding layer 2d are inclined to be widened toward the bottom side, and in that the primer layer 71 is not provided between the sintered bonding layer 2d and the sealing resin 72. The semiconductor device of the third comparative example has low adhesion between the sealing resin 72 and the sintered bonding layer 2d, and thus causes a separation at the interface between the sealing resin 72 and the sintered bonding layer 2d to provide a gap 73. While a crack 25 is caused only in a part in which the separation is caused to lead to a break, the separation-caused part can vary and the part in which the crack 25 is caused can also vary, leading to variation in the life span accordingly.

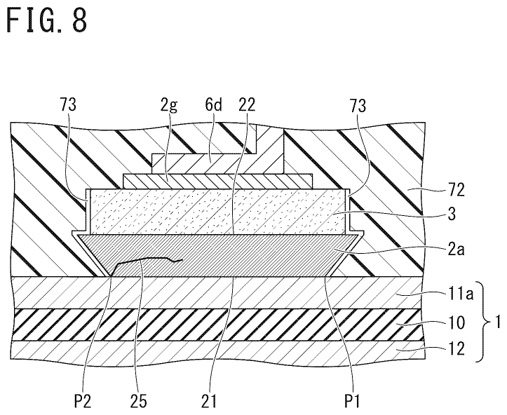

Next, a semiconductor device of a fourth comparative example is described below. As illustrated in FIG. 8, the semiconductor device of the fourth comparative example differs from the semiconductor device according to the first embodiment illustrated in FIG. 3 in that the primer layer 71 is not provided between the sintered bonding layer 2a and the sealing resin 72. The semiconductor device of the fourth comparative example has low adhesion between the sealing resin 72 and the sintered bonding layer 2a, and thus causes a separation at the interface between the sealing resin 72 and the sintered bonding layer 2a to provide a gap 73. While a crack 25 is caused only in a part in which the separation is caused to lead to a break, the separation-caused part can vary and the part in which the crack 25 is caused can also vary, leading to variation in the life span accordingly.

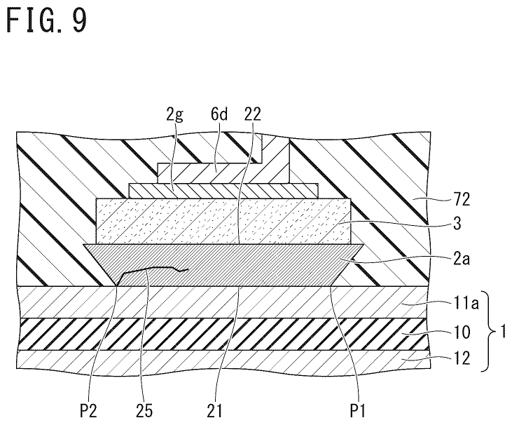

Next, a semiconductor device of a fifth comparative example is described below. As illustrated in FIG. 9, the semiconductor device of the fifth comparative example differs from the semiconductor device according to the first embodiment illustrated in FIG. 3 in that the primer layer 71 is not provided between the sintered bonding layer 2a and the sealing resin 72, and in that the sealing resin 72 includes gel. The semiconductor device of the fifth comparative example, in which the sealing resin 72 includes gel, impedes an increase in high-heat resistance.

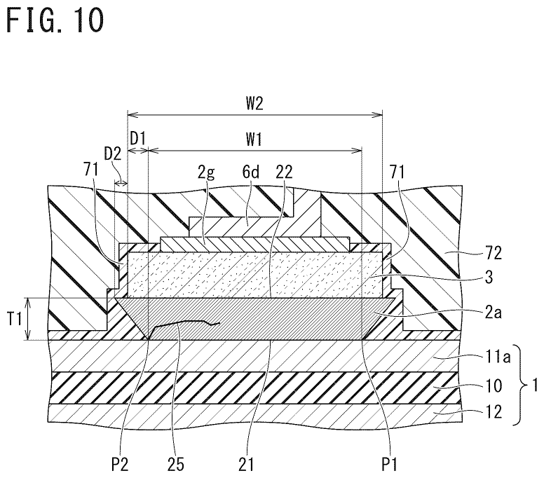

As compared with the semiconductor device of the first comparative example illustrated in FIG. 5 and the semiconductor device of the second comparative example illustrated in FIG. 6, the semiconductor device according to the first embodiment illustrated in FIG. 3 has the shape (the inverted fillet shape) in which the outer edge of the bonding interface 21 between the sintered bonding layer 2a and the conductive plate 11a is located on the inside of the outer circumference of the semiconductor chip 3 and is located on the inside of the outer edge of the bonding interface 22 between the sintered bonding layer 2a and the semiconductor chip 3. This configuration can positively cause cracks 25 starting from the stress-concentrated parts P1 and P2 in the sintered bonding layer 2a, so as to enable the rate limiting of the life span in the sintered bonding layer 2a, as illustrated in FIG. 10. The semiconductor device according to the first embodiment has a shorter life span than the respective semiconductor devices of the first and second comparative examples, but can reduce variation in the life span while allowing a relatively long-life span as compared with the case of being made from solder.

Further, as compared with the semiconductor device of the third comparative example illustrated in FIG. 7 and the semiconductor device of the fourth comparative example illustrated in FIG. 8, the semiconductor device according to the first embodiment includes the primer layer 71 provided between the sintered bonding layer 2a and the sealing resin 72, so as to reliably ensure the adhesion between the sintered bonding layer 2a and the sealing resin 72. The semiconductor device according to the first embodiment thus can prevent a separation at the interface between the sintered bonding layer 2a and the sealing resin 72, so as to reduce variation in the life span to stabilize the life span accordingly.

Further, as compared with the semiconductor device of the fifth comparative example illustrated in FIG. 9, the semiconductor device according to the first embodiment, in which the sealing resin 72 includes thermosetting resin such as epoxy resin, can enhance the high-heat resistance more than the case in which the sealing resin 72 includes gel.

Further, the configuration of the semiconductor device of the fourth comparative example illustrated in FIG. 8, in which the space between the sintered bonding layer 2a and the sealing resin 72 decreases as closer to the outer edge of the bonding interface 21, impedes the entrance of the inorganic filler included in the sealing resin 72 between the sintered bonding layer 2a and the sealing resin 72, and thus could provide a gap between the sintered bonding layer 2a and the sealing resin 72. As compared with this, the semiconductor device according to the first embodiment with the configuration as described above facilitates the entrance of the primer layer 71 between the sintered bonding layer 2a and the sealing resin 72, so as to easily fill the space between the sintered bonding layer 2a and the sealing resin 72.

Further, the configuration of the semiconductor device according to the first embodiment, in which the width W2 of the bonding interface 22 between the sintered bonding layer 2a and the semiconductor chip 3 is greater than the width W1 of the outer edge of the bonding interface 21 between the sintered bonding layer 2a and the conductive plate 11a, can release heat from the semiconductor chip 3 efficiently and can also avoid damage to the edge of the semiconductor chip 3.

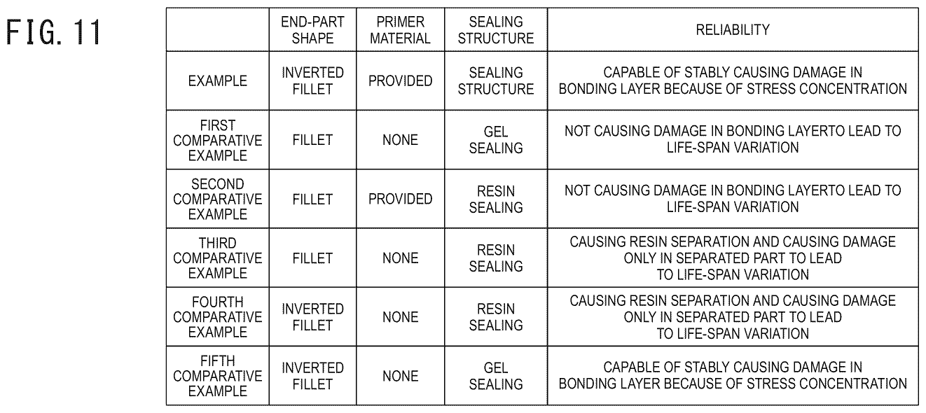

FIG. 11 is a table showing results of a reliability test (a power cycle test) executed for the semiconductor device according to the first embodiment (the example) illustrated in FIG. 3, the semiconductor device of the first comparative example illustrated in FIG. 5, the semiconductor device of the second comparative example illustrated in FIG. 6, the semiconductor device of the third comparative example illustrated in FIG. 7, the semiconductor device of the fourth comparative example illustrated in FIG. 8, and the semiconductor device of the fifth comparative example illustrated in FIG. 9. The results revealed that the semiconductor device of the first comparative example illustrated in FIG. 5 and the semiconductor device of the second comparative example illustrated in FIG. 6 caused a break not in the sintered bonding layer 2d but in other parts. The results also revealed that the semiconductor device of the third comparative example illustrated in FIG. 7 and the semiconductor device of the fourth comparative example illustrated in FIG. 8 caused a separation at the interface between the respective sintered bonding layers 2a and 2d and the sealing resin 72 and caused damage to the separated part, leading to variation in the life span accordingly. The results also revealed that the semiconductor device of the fifth comparative example illustrated in FIG. 9 stably led to a break in the sintered bonding layer 2a because of a stress concentration.

### <Method of Manufacturing Semiconductor Device>

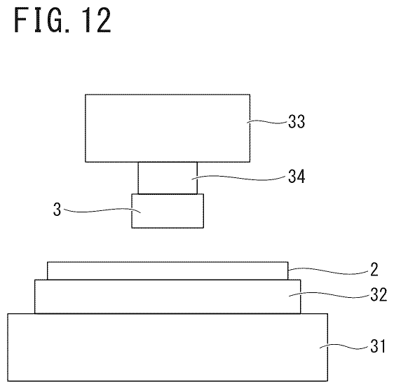

A method of manufacturing (assembling) the semiconductor device according to the first embodiment is described below. First, as illustrated in FIG. 12, a rubber sheet 32 is placed on the top surface of a base stand 31, and a sintering sheet 2 that is a sheet-like sintering material is further placed on the top surface of the rubber sheet 32. The semiconductor chip 3 is then led to adhere to a sticking part 34 of a mounter head 33 so that the bottom surface of the semiconductor chip 3 is opposed to the top surface of the sintering sheet 2.

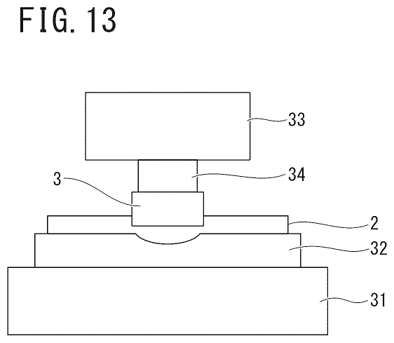

Next, as illustrated in FIG. 13, the mounter head 33 is led to go down so as to push the bottom surface of the semiconductor chip 3 against the sintering sheet 2. This step causes the stress to be concentrated on the edge of the bottom surface of the semiconductor chip 3, so as to press a part of the sintering sheet 2 on the edge side of the bottom surface of the semiconductor chip 3 to decrease the thickness of the sintering sheet 2 more in the part on the edge side of the bottom surface of the semiconductor chip 3 than in a part corresponding to the middle of the bottom surface of the semiconductor chip 3. The sintering sheet 2 thus has a lower porosity in the relatively-thin part on the edge side than in the relatively-thick part in the middle. The step of pushing the bottom surface of the semiconductor chip 3 against the sintering sheet 2 may include a step of heating and a step of applying pressure executed simultaneously so as to facilitate the step of transferring the sintering sheet 2.

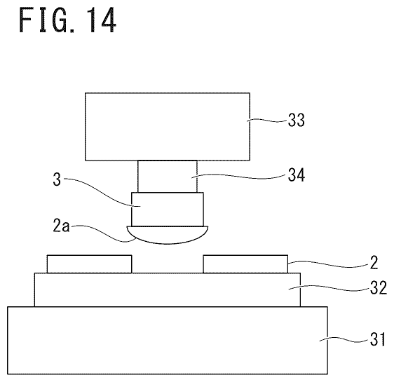

Next, as illustrated in FIG. 14, the mounter head 33 is led to be lifted up so that a part of the sintering sheet 2 is cut off and the sintered bonding layer 2a as a part of the sintering sheet 2 is transferred to the bottom surface of the semiconductor chip 3. The sintered bonding layer 2a has a thickness that is relatively thick in the middle and is relatively thin on the edge side.

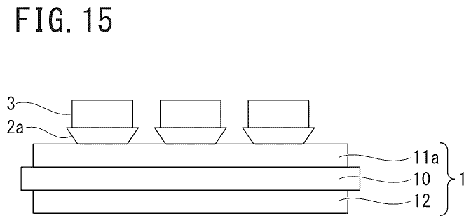

Next, the insulated circuit substrate 1 is prepared, as illustrated in FIG. 15. FIG. 15 omits the illustration of the conductive plate 11b of the insulated circuit substrate 1 illustrated in FIG. 1. The plural semiconductor chips 3 each equipped with the sintered bonding layer 2a are mounted on the conductive plate 11a of the insulated circuit substrate 1 by use of a conveyer, for example. While FIG. 15 illustrates the case of including the plural semiconductor chips 3 each equipped with the sintered bonding layer 2a, the present embodiment may include the single semiconductor chip 3 equipped with the sintered bonding layer 2a as illustrated in FIG. 1.

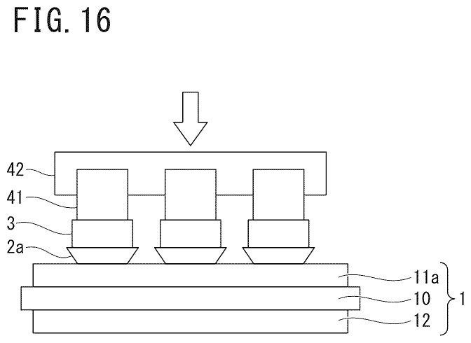

Next, as illustrated in FIG. 16, a pressure is applied to the semiconductor chips 3 from the top surface side by pressing parts 41 made from silicon (Si) rubber attached to a metal die 42 of a pressing device. Executing heat treatment while the semiconductor chips 3 are pressed causes a sintering reaction in the sintered bonding layers 2a. This sintering reaction is caused under the conditions in which a pressing force is set in a range of about 1 MPa or greater and 60 MPa or less, a heating temperature is set in a range of about 150° C. or higher and 350° C. or lower, and a heating time is set in a range about 1 minute or longer and 5 minutes or shorter, for example. This step leads the insulated circuit substrate 1 and the respective semiconductor chips 3 to be bonded together with the sintered bonding layers 2a interposed.

Next, the case 5 is placed on the periphery of the insulated circuit substrate 1 and the semiconductor chips 3, and the insulated circuit substrate 1, the semiconductor chips 3, and the external terminals 4a and 4b are connected together via the wiring members such as the bonding wires 6a, 6b, and 6c (refer to FIG. 1). Next, the primer layer 71 is formed to cover the respective surfaces of the sintered bonding layer 2a and the semiconductor chips 3 by spray application, immersion, or application with a dispenser (refer to FIG. 1). Thereafter, the surface of the primer layer 71 is sealed to be covered with the sealing resin 72, so as to complete the semiconductor device according to the first embodiment illustrated in FIG. 1.

The method of manufacturing the semiconductor device according to the first embodiment can ensure the high heat-resistance properties, and also reduce or avoid variation in the life span derived from a separation at the interface between the sintered bonding layer 2a and the sealing resin 72.

While the method of manufacturing the semiconductor device according to the first embodiment is illustrated above with the case of transferring a part of the sintering sheet 2 to the bottom surfaces of the semiconductor chips 3, the sintered bonding layer 2a in a paste state may be applied to the bottom surfaces of the semiconductor chips 3 by screen printing or the like so as to have a thickness thicker in the middle than in the edge parts.

Further, the method of manufacturing the semiconductor device according to the first embodiment is illustrated above with the case of mounting the rubber sheet 32 on the top surface of the base stand 31, but does not necessarily use the rubber sheet 32 and may use the base stand 31 provided with recesses. The method in this case may mount the sintering sheet 2 over the recesses to push the bottom surfaces of the semiconductor chips 3 against the sintering sheet 2, so as to allow the transfer of the sintered bonding layer 2a having a thickness thicker in the middle than in the edge parts.

### Second Embodiment

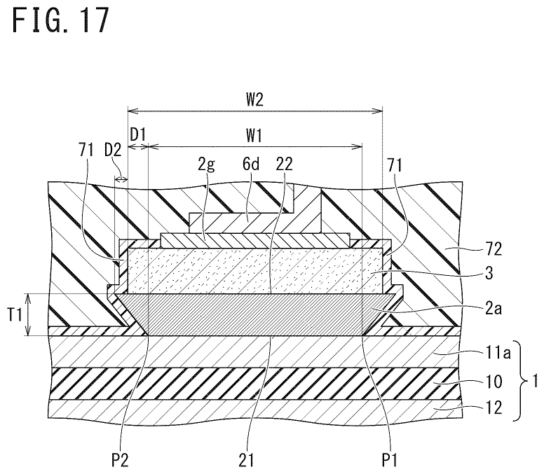

A semiconductor device according to a second embodiment differs from the semiconductor device according to the first embodiment illustrated in FIG. 3 in that the primer layer 71 and the sealing resin 72 both penetrate into the region between the sintered bonding layer 2a and the conductive plate 11a, as illustrated in FIG. 17. The primer layer 71 is provided to have a substantially constant thickness along the side surfaces of the sintered bonding layer 2a. The shape of the primer layer 71 can be determined as appropriate depending on the viscosity and the applied amount of the primer layer 71, for example. The other configurations of the semiconductor device according to the second embodiment are the same as those of the semiconductor device according to the first embodiment, and overlapping explanations are not repeated below. The semiconductor device according to the second embodiment can be manufactured by the same process as the method of manufacturing the semiconductor device according to the first embodiment.

The semiconductor device according to the second embodiment with the configuration, which can positively cause cracks starting from the stress-concentrated parts P1 and P2 in the sintered bonding layer 2a so as to intentionally lead to a break, can avoid variation in the life span of the semiconductor device. Further, the configuration in which the primer layer 71 penetrates into the region between the sintered bonding layer 2a and the sealing resin 72 can reduce the variation in the life span derived from a separation of the sealing resin 72. Further, the configuration in which the width W2 of the bonding interface 22 between the sintered bonding layer 2a and the semiconductor chip 3 is greater than the width W1 of the outer edge of the bonding interface 21 between the sintered bonding layer 2a and the conductive plate 11a, can release the heat from the semiconductor chip 3 efficiently and can also avoid damage to the edge of the semiconductor chip 3.

### Third Embodiment

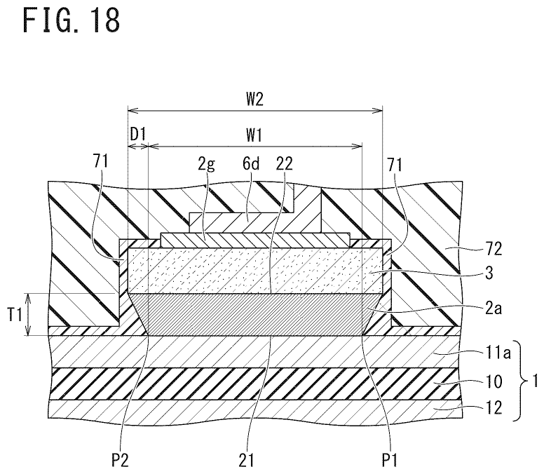

A semiconductor device according to a third embodiment has the same configuration as the semiconductor device according to the first embodiment illustrated in FIG. 3 in that the outer edge of the bonding interface 21 between the sintered bonding layer 2a and the conductive plate 11a is located on the inside of the outer circumference of the semiconductor chip 3 and is located on the inside of the outer edge of the bonding interface 22 between the sintered bonding layer 2a and the semiconductor chip 3, as illustrated in FIG. 18. The semiconductor device according to the third embodiment differs from the semiconductor device according to the first embodiment in that the outer edge of the sintered bonding layer 2a on the top surface side (toward the semiconductor chip 3) conforms to the outer circumference of the semiconductor chip 3 and conforms to the outer edge of the bonding interface 22 between the sintered bonding layer 2a and the semiconductor chip 3.

The other configurations of the semiconductor device according to the third embodiment are the same as those of the semiconductor device according to the first embodiment, and overlapping explanations are not repeated below. The semiconductor device according to the third embodiment can be manufactured by the same process as the method of manufacturing the semiconductor device according to the first embodiment.

The semiconductor device according to the third embodiment with the configuration, which can positively cause cracks starting from the stress-concentrated parts P1 and P2 in the sintered bonding layer 2a so as to intentionally lead to a break, can avoid variation in the life span of the semiconductor device. Further, the configuration in which the primer layer 71 penetrates into the region between the sintered bonding layer 2a and the sealing resin 72 can reduce the variation in the life span derived from a separation of the sealing resin 72. Further, the configuration in which the outer edge of the bonding interface 22 between the sintered bonding layer 2a and the semiconductor chip 3 conforms to the outer circumference of the semiconductor chip 3, can prevent a problem of a drop of a part of the sintered bonding layer 2a, as compared with the case of projecting to the outside of the outer circumference of the semiconductor chip 3.

### Fourth Embodiment

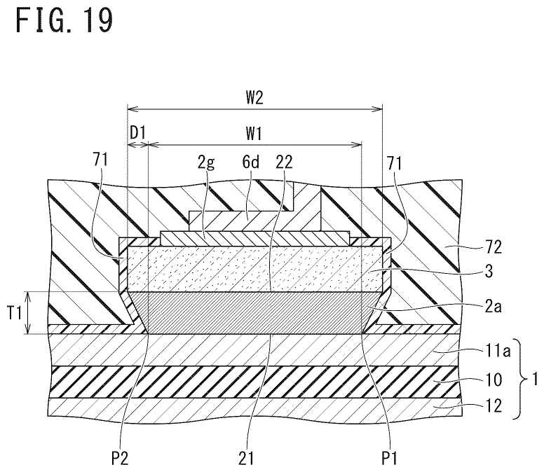

A semiconductor device according to a fourth embodiment differs from the semiconductor device according to the third embodiment illustrated in FIG. 18 in that the primer layer 71 and the sealing resin 72 both penetrate into the region between the sintered bonding layer 2a and the conductive plate 11a, as illustrated in FIG. 19. The primer layer 71 is provided to have a substantially constant thickness along the side surfaces of the sintered bonding layer 2a. The shape of the primer layer 71 can be determined as appropriate depending on the viscosity and the applied amount of the primer layer 71, for example. The other configurations of the semiconductor device according to the fourth embodiment are the same as those of the semiconductor device according to the third embodiment, and overlapping explanations are not repeated below. The semiconductor device according to the fourth embodiment can be manufactured by the same process as the method of manufacturing the semiconductor device according to the third embodiment.

The semiconductor device according to the fourth embodiment with the configuration, which can positively cause cracks starting from the stress-concentrated parts P1 and P2 in the sintered bonding layer 2a so as to intentionally lead to a break, can avoid variation in the life span of the semiconductor device. Further, the configuration in which the primer layer 71 penetrates into the region between the sintered bonding layer 2a and the sealing resin 72 can reduce the variation in the life span derived from a separation of the sealing resin 72. Further, the configuration in which the outer edge of the bonding interface 22 between the sintered bonding layer 2a and the semiconductor chip 3 conforms to the outer circumference of the semiconductor chip 3, can prevent a problem of a drop of a part of the sintered bonding layer 2a, as compared with the case of projecting to the outside of the outer circumference of the semiconductor chip 3.

### Fifth Embodiment

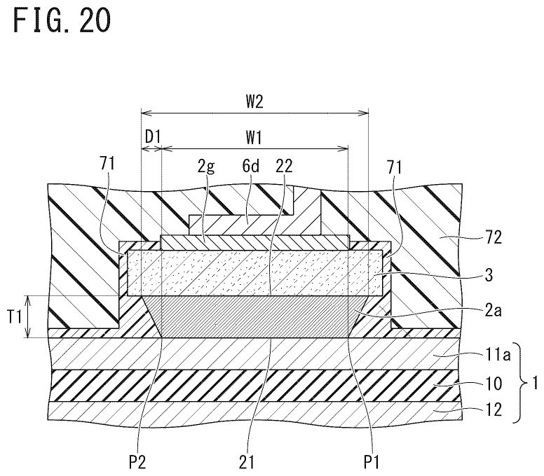

A semiconductor device according to a fifth embodiment has the same configuration as the semiconductor device according to the first embodiment illustrated in FIG. 3 in that the outer edge of the bonding interface 21 between the sintered bonding layer 2a and the conductive plate 11a is located on the inside of the outer circumference of the semiconductor chip 3 and is located on the inside of the outer edge of the bonding interface 22 between the sintered bonding layer 2a and the semiconductor chip 3, as illustrated in FIG. 20. The semiconductor device according to the fifth embodiment differs from the semiconductor device according to the first embodiment in that the outer edge of the sintered bonding layer 2a on the top surface side (toward the semiconductor chip 3) is located on the inside of the outer circumference of the semiconductor chip 3 and conforms to the outer edge of the bonding interface 22 between the sintered bonding layer 2a and the semiconductor chip 3.

The other configurations of the semiconductor device according to the fifth embodiment are the same as those of the semiconductor device according to the first embodiment, and overlapping explanations are not repeated below. The semiconductor device according to the fifth embodiment can be manufactured by the same process as the method of manufacturing the semiconductor device according to the first embodiment.

The semiconductor device according to the fifth embodiment with the configuration, which can positively cause cracks starting from the stress-concentrated parts P1 and P2 in the sintered bonding layer 2a so as to intentionally lead to a break, can avoid variation in the life span of the semiconductor device. Further, the configuration in which the primer layer 71 penetrates into the region between the sintered bonding layer 2a and the sealing resin 72 can reduce the variation in the life span derived from a separation of the sealing resin 72. Further, the configuration in which the outer edge of the bonding interface 22 between the sintered bonding layer 2a and the semiconductor chip 3 is located on the inside of the outer circumference of the semiconductor chip 3, can prevent a problem of a drop of a part of the sintered bonding layer 2a, as compared with the case of projecting to the outside of the outer circumference of the semiconductor chip 3.

### Sixth Embodiment

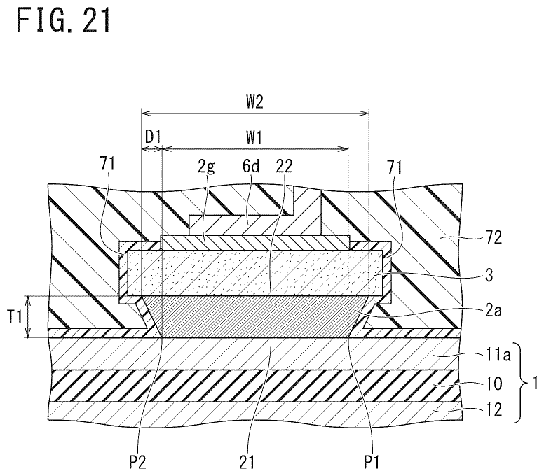

A semiconductor device according to a sixth embodiment differs from the semiconductor device according to the fifth embodiment illustrated in FIG. 20 in that the primer layer 71 and the sealing resin 72 both penetrate into the region between the sintered bonding layer 2a and the conductive plate 11a, as illustrated in FIG. 21. The primer layer 71 is provided to have a substantially constant thickness along the side surfaces of the sintered bonding layer 2a. The shape of the primer layer 71 can be determined as appropriate depending on the viscosity and the applied amount of the primer layer 71, for example. The other configurations of the semiconductor device according to the sixth embodiment are the same as those of the semiconductor device according to the fifth embodiment, and overlapping explanations are not repeated below. The semiconductor device according to the sixth embodiment can be manufactured by the same process as the method of manufacturing the semiconductor device according to the fifth embodiment.

The semiconductor device according to the sixth embodiment with the configuration, which can positively cause cracks starting from the stress-concentrated parts P1 and P2 in the sintered bonding layer 2a so as to intentionally lead to a break, can avoid variation in the life span of the semiconductor device. Further, the configuration in which the primer layer 71 penetrates into the region between the sintered bonding layer 2a and the sealing resin 72 can reduce the variation in the life span derived from a separation of the sealing resin 72. Further, the configuration in which the outer edge of the bonding interface 22 between the sintered bonding layer 2a and the semiconductor chip 3 is located on the inside of the outer circumference of the semiconductor chip 3, can prevent a problem of a drop of a part of the sintered bonding layer 2a, as compared with the case of projecting to the outside of the outer circumference of the semiconductor chip 3.

### Seventh Embodiment

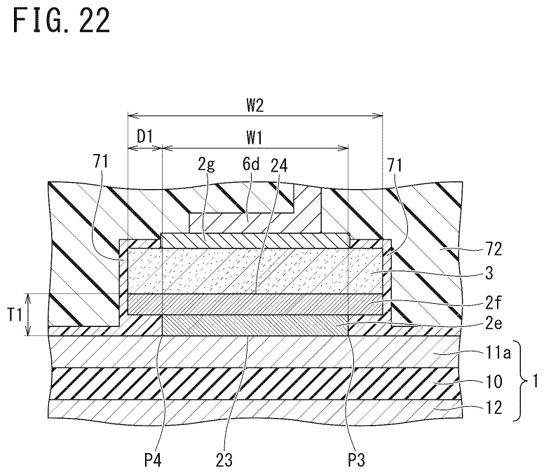

A semiconductor device according to a seventh embodiment has the same configuration as the semiconductor device according to the first embodiment illustrated in FIG. 3 in that an outer edge of a bonding interface 23 between a sintered bonding layer (2e, 2f) and the conductive plate 11a is located on the inside of the outer circumference of the semiconductor chip 3 and is located on the inside of an outer edge of a bonding interface 24 between the semiconductor chip 3 and the sintered bonding layer (2e, 2f), as illustrated in FIG. 22. The semiconductor device according to the seventh embodiment differs from the semiconductor device according to the first embodiment in that the sintered bonding layer (2e, 2f) has a two-layer structure including a first bonding layer (a lower-side bonding layer) 2e bonded to the conductive plate 11a and a second bonding layer (an upper-side bonding layer) 2f for bonding the lower-side bonding layer 2e and the semiconductor chip 3 together.

The lower-side bonding layer 2e and the upper-side bonding layer 2f each include sintering material in a paste state or in a sheet-like state, as in the case of the sintered bonding layer 2a in the semiconductor device according to the first embodiment. The lower-side bonding layer 2e and the upper-side bonding layer 2f may include the material that is either the same or different from each other. The lower-side bonding layer 2e may have the same thickness as the upper-side bonding layer 2f, or may have a thickness that is either thinner or greater than that of the upper-side bonding layer 2f.

The outer edge of the bonding interface 23 between the lower-side bonding layer 2e and the conductive plate 11a is located on the inside of the outer edge of the bonding interface 24 between the semiconductor chip 3 and the upper-side bonding layer 2f. The stress-concentrated parts P3 and P4 are thus provided at the positions on the outer edge of the bonding interface 23 between the lower-side bonding layer 2e and the conductive plate 11a. The other configurations of the semiconductor device according to the seventh embodiment are the same as those of the semiconductor device according to the first embodiment, and overlapping explanations are not repeated below.

The semiconductor device according to the seventh embodiment with the configuration, which can positively cause cracks starting from the stress-concentrated parts P3 and P4 in the lower-side bonding layer 2e of the sintered bonding layer (2e, 2f) so as to intentionally lead to a break, can avoid variation in the life span of the semiconductor device. Further, the configuration in which the primer layer 71 penetrates into the region between the sintered bonding layer (2e, 2f) and the sealing resin 72 can reduce the variation in the life span derived from a separation of the sealing resin 72.

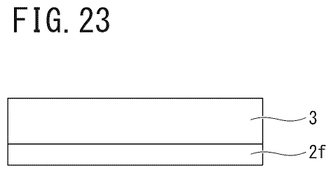

An example of a method of manufacturing the semiconductor device according to the seventh embodiment is described below. First, as illustrated in FIG. 23, the upper-side bonding layer 2f in a paste state is applied evenly to the bottom surface of the semiconductor chip 3 by screen printing or the like, and the upper-side bonding layer 2f is then dried. Alternatively, the upper-side bonding layer 2f may be formed evenly on the bottom surface of the semiconductor chip 3 by a transfer of a sintering sheet. Alternatively, the upper-side bonding layer 2f may be preliminarily formed on a bottom surface of a semiconductor wafer before diced into each piece of the semiconductor chips 3.

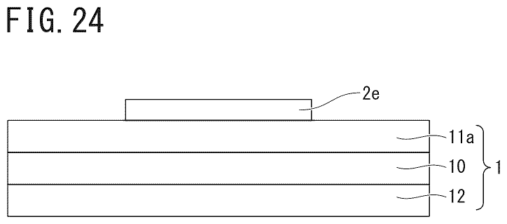

Further, as illustrated in FIG. 24, the lower-side bonding layer 2e in a paste state is applied to the top surface of the conductive plate 11a of the insulated circuit substrate 1 by screen printing or the like so as to have a smaller area than the upper-side bonding layer 2f, and the lower-side bonding layer 2e is then dried. Alternatively, the lower-side bonding layer 2e made of a sintering sheet may be deposited on the top surface of the conductive plate 11a of the insulated circuit substrate 1.

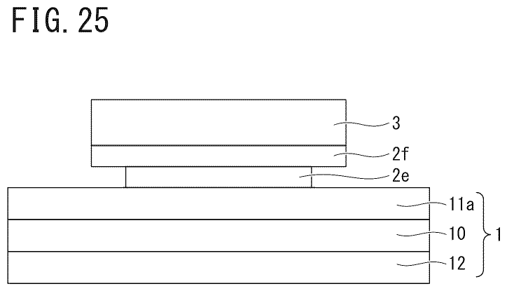

Next, as illustrated in FIG. 25, the upper-side bonding layer 2f provided on the bottom surface of the semiconductor chip 3 illustrated in FIG. 23 and the lower-side bonding layer 2e provided on the top surface of the insulated circuit substrate 1 are attached to each other to be subjected to pressure-applying treatment and heating treatment so that the insulated circuit substrate 1 and the semiconductor chip 3 are bonded together with the sintered bonding layer (2e, 2f) interposed. The other steps of the method of manufacturing the semiconductor device according to the seventh embodiment are the same as those of the method of manufacturing the semiconductor device according to the first embodiment, and overlapping explanations are not repeated below.

While the semiconductor device according to the seventh embodiment is illustrated above with the configuration in which the sintered bonding layer (2e, 2f) has the two-layer structure including the lower-side bonding layer 2e and the upper-side bonding layer 2f, the bonding layer may have a stacked structure including three or more layers including sintering material. For example, when the bonding layer has a three-layer structure, a third bonding layer (an intermediate bonding layer) may be formed on the top surface of the lower-side bonding layer 2e after the lower-side bonding layer 2e is formed on the top surface of the conductive plate 11a of the insulated circuit substrate 1 so as to have a larger area than the lower-side bonding layer 2e and have a smaller area than the upper-side bonding layer 2f.

While the semiconductor device according to the seventh embodiment is illustrated above with the configuration in which the outer circumference of the upper-side bonding layer 2f conforms to the outer circumference of the semiconductor chip 3 and conforms to the outer edge of the bonding interface 24 between the semiconductor chip 3 and the upper-side bonding layer 2f, the outer circumference of the upper-side bonding layer 2f may be located on the inside of the outer circumference of the semiconductor chip 3 and conform to the outer edge of the bonding interface 24 between the semiconductor chip 3 and the upper-side bonding layer 2f. Further, the semiconductor device according to the seventh embodiment is illustrated above with the case in which the outer circumference of the upper-side bonding layer 2f conforms to the outer circumference of the semiconductor chip 3, but the outer circumference of the upper-side bonding layer 2f may project to the outside from the outer circumference of the semiconductor chip 3.

### Eighth Embodiment

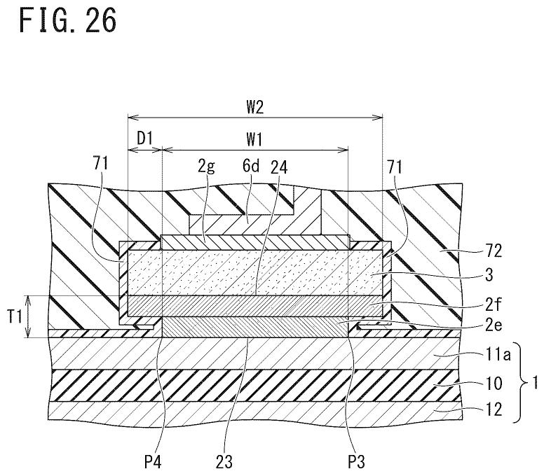

A semiconductor device according to an eighth embodiment differs from the semiconductor device according to the seventh embodiment illustrated in FIG. 22 in that the primer layer 71 and the sealing resin 72 both penetrate into the region between the sintered bonding layer (2e, 2f) and the conductive plate 11a, as illustrated in FIG. 26. The primer layer 71 is provided to have a substantially constant thickness along the side surfaces of the sintered bonding layer (2e, 2f). The shape of the primer layer 71 can be determined as appropriate depending on the viscosity and the applied amount of the primer layer 71, for example. The other configurations of the semiconductor device according to the eighth embodiment are the same as those of the semiconductor device according to the seventh embodiment, and overlapping explanations are not repeated below. The semiconductor device according to the eighth embodiment can be manufactured by the same process as the method of manufacturing the semiconductor device according to the seventh embodiment.

The semiconductor device according to the eighth embodiment with the configuration, which can positively cause cracks starting from the stress-concentrated parts P3 and P4 in the lower-side bonding layer 2e of the sintered bonding layer (2e, 2f) so as to intentionally lead to a break, can avoid variation in the life span of the semiconductor device. Further, the configuration in which the primer layer 71 penetrates into the region between the sintered bonding layer (2e, 2f) and the sealing resin 72 can reduce the variation in the life span derived from a separation of the sealing resin 72.

### Other Embodiments

As described above, the invention has been described according to the first to eighth embodiments, but it should not be understood that the description and drawings implementing a portion of this disclosure limit the invention. Various alternative embodiments of the present invention, examples, and operational techniques will be apparent to those skilled in the art from this disclosure.

While the respective semiconductor devices according to the first to eighth embodiments have been illustrated above with the case in which the connection of the semiconductor chip 3 is executed via the bonding wires 6a, 6b, and 6c, or the lead frame 6d that are the wiring members, the present invention is not limited to this case. For example, the present invention may also be applied to a semiconductor device in which an implanted substrate including a printed substrate to which pin-like post electrodes are inserted is provided over the semiconductor chip 3 so that the semiconductor chip 3 and the post electrodes are connected to each other.

In addition, the respective configurations disclosed in the first to eighth embodiments can be combined together as appropriate without contradiction with each other. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

1. A semiconductor device comprising:
a conductive plate having a main surface;
a semiconductor chip arranged to be opposed to the main surface of the conductive plate;
a sintered bonding layer arranged between the conductive plate and the semiconductor chip;
a sealing resin provided to seal the semiconductor chip and the sintered bonding layer; and
a primer layer arranged between the sintered bonding layer and the sealing resin,
wherein a first outer edge of a bonding interface between the sintered bonding layer and the conductive plate is located on an inside of an outer circumference of the semiconductor chip and is located on an inside of a second outer edge of a bonding interface between the sintered bonding layer and the semiconductor chip.

2. The semiconductor device of claim 1, wherein only the primer layer penetrates into a region between the sintered bonding layer and the conductive plate.

3. The semiconductor device of claim 1, wherein a distance between an outer edge of the sintered bonding layer and the conductive plate is gradually decreased toward the first outer edge, and the primer layer penetrates to reach the first outer edge.

4. The semiconductor device of claim 2, wherein a distance between an outer edge of the sintered bonding layer and the conductive plate is gradually decreased toward the first outer edge, and the primer layer penetrates to reach the first outer edge.

5. The semiconductor device of claim 1, wherein the primer layer and the sealing resin penetrate into a region between the sintered bonding layer and the conductive plate.

6. The semiconductor device of claim 1, wherein the primer layer has a greater coefficient of linear thermal expansion than the sealing resin.

7. The semiconductor device of claim 1, wherein the primer layer includes polyamide, polyimide, or polyamide imide.

8. The semiconductor device of claim 1, wherein the sealing resin includes epoxy resin, phenol resin, or maleimide resin.

9. The semiconductor device of claim 3, wherein the sealing resin includes inorganic filler.

10. The semiconductor device of claim 1, wherein an outer edge of the sintered bonding layer toward the semiconductor chip projects outward from the outer circumference of the semiconductor chip.

11. The semiconductor device of claim 1, wherein an outer edge of the sintered bonding layer toward the semiconductor chip conforms to the outer circumference of the semiconductor chip.

12. (canceled)

13. (canceled)

14. (canceled)

15. The semiconductor device of claim 1, wherein an outer edge of the sintered bonding layer toward the semiconductor chip is located on the inside of the outer circumference of the semiconductor chip.

16. The semiconductor device of claim 1, wherein a surface of the sintered bonding layer toward the conductive plate on an outside of the first outer edge is a curved surface convex toward the conductive plate.

17. The semiconductor device of claim 1, wherein a stress-concentrated part is provided at the first outer edge.

18. The semiconductor device of claim 1, wherein a porosity in a part of the sintered bonding layer on an inside of the first outer edge is higher than a porosity in a part of the sintered bonding layer on the inside of the second outer edge and on an outside of the first outer edge.

19. The semiconductor device of claim 1, wherein the sintered bonding layer includes
a first bonding layer bonded to the conductive plate, and
a second bonding layer provided to bond the first bonding layer and the semiconductor chip together.

20. The semiconductor device of claim 1, wherein the first outer edge has a triple-junction point at which the sintered bonding layer, the conductive plate, and the primer layer are in contact with each other.

21. The semiconductor device of claim 9, wherein an amount of the inorganic filler included is 10% by mass or greater.

22. The semiconductor device of claim 9, wherein the sealing resin does not penetrate into a region between the sintered bonding layer and the conductive plate.

23. The semiconductor device of claim 9, wherein the sealing resin is provided only on an outside of an outer edge of the sintered bonding layer.
